(19) United States
(12) Patent Application Publication
(10) Pub. No.: US 2007/0075395 A1
(43) Pub. Date: Apr. 5, 2007

(54) CAPACITOR OF A SEMICONDUCTOR DEVICE

(76) Inventor: Yong-Soo Ahn, Gyeongi-do (KR)

Correspondence Address: SHERR & NOURSE, PLLC, 620 HERNDON PARKWAY, SUITE 200, HERNDON, VA, 20170, US

(21) Appl. No.: 11/537,668

(22) Filed: Oct. 2, 2006

(30) Foreign Application Priority Data
Oct. 4, 2005 (KR) 10-2005-0093021

(51) Int. Cl. H01L 29/00

(52) U.S. Cl. 257/516

(57) ABSTRACT

A capacitor of a semiconductor device and a method of fabricating a capacitor in a semiconductor device are disclosed. The capacitor may include a bottom electrode formed on a semiconductor substrate, an insulation layer having different regions having different thicknesses, and a top electrode over a region of the insulation layer that has a relatively great thickness.

The present application claims priority under 35 U.S.C. 119 and 35 U.S.C. 365 to Korean Patent Application No. 10-2005-093021(filed on Oct. 4, 2005), which is hereby incorporated by reference in its entirety.

### BACKGROUND OF THE INVENTION

1. Field of the Invention

Embodiments of the present invention relates to a capacitor of a semiconductor device and/or a method of fabricating a capacitor of a semiconductor device.

2. Description of the Related Art

Merged memory logic (MML) is an integrated device including a memory cell array (e.g. a dynamic random access memory (DRAM)) and an analog or peripheral circuit on a single chip. In MML devices, multimedia functions may be improved to achieve higher degrees of the integration and faster speeds.

Semiconductor devices are under development that include a high-capacity capacitor in analog circuits that require high-speed operation. A capacitor having a polysilicon/insulator/polysilicon (PIP) structure (i.e. including sequentially layering of a polysilicon layer, an insulator layer, and a polysilicon layer) may have a top electrode and a bottom electrode formed of a conductive polysilicon material. Accordingly, there may be an oxidation reaction during formation of a top electrode, a bottom electrode, and a thin dielectric layer interface, resulting in the formation of a native oxide layer, thereby decreasing the size of a capacitor.

To prevent a decrease in the size of a capacitor, a capacitor may have a metal/insulator/silicon (MIS) or metal/insulator/metal (MIM) structure. Since a MIM-type capacitor may have a relatively small resistivity and a parasitic capacitance due to depletion in inside the capacitor, it may be used in high-performance semiconductor devices. Since MIM-type analog capacitors needs to be integrated with other semiconductor devices, MIM-type analog capacitors may need to be electrically connected to a semiconductor device through a metal line (e.g. an interconnection line).

FIGS. 1A to 1F are sectional views illustrating a method for fabricating a capacitor of a related art semiconductor device. FIG. 1A illustrates bottom electrode layer 20 (e.g. formed using metal or metal nitride) on semiconductor substrate 10 (e.g. a silicon wafer). FIG. 1B illustrates insulation layer 30 (which may serve as an insulator) and top electrode layer 40 formed sequentially over bottom electrode layer 20. Top electrode layer 40 may be formed of metal or metal nitride. A photoresist layer may be formed over top electrode layer 40. The photoresist layer may be patterned to form first mask layer 50 for a top electrode of a capacitor in a semiconductor device.

Fig. 1C illustrates the result of using first mask layer 50 as an etching mask to etch top electrode layer 40 and insulation layer 30 to form the top electrode 42. First mask layer 50 may then be removed. Fig. 1D illustrates anti reflective layer 60 formed over bottom electrode layer 20, covering top electrode 42 and coating bottom electrode layer 20. Anti reflective layer 60 may be formed of Ti or TiN. A photoresist layer may be formed over anti reflective layer 60. Anti reflective layer may be patterned to form second mask layer 52 for a bottom electrode of a capacitor in a semiconductor device.

FIG. 1E illustrates the result of using the second mask layer 52 as an etching mask. Anti reflective layer 60 and bottom electrode layer 20 may be etched to form bottom electrode 22. Fig. 1F illustrates the removal of second mask layer 52 to form a capacitor of a semiconductor device.

To reduce the high reflectivity of bottom electrode 22, after forming the top electrode 42, bottom electrode layer 20 may be coated using anti reflective layer 60. Bottom electrode 22 may be formed using patterning and etching processes. Accordingly, there may be a relatively high number of manufacturing processes in processes illustrated in FIGS. 1A through 1F. Additionally, since bottom electrode 22 is exposed, capacitor characteristics may deteriorate due to leakage current between top electrode 42 and bottom electrode 22.

### SUMMARY OF THE INVENTION

Embodiments provide a capacitor in a semiconductor device that may be formed with simplified fabricating processes. Embodiments provide a capacitor in a semiconductor device that may be capable of substantially preventing or significantly reducing leakage current, thereby improving capacitor characteristics.

Additional advantages, objects, and features of embodiments are set forth in part in the description which follows and in part will become apparent to those having ordinary skill in the art upon examination of the following or may be learned from practice of embodiments. Objectives and other advantages of embodiments may be realized and attained by the structure particularly pointed out in the written description and claims hereof as well as the appended drawings.

Embodiments relate to a capacitor in a semiconductor device, the capacitor including: a bottom electrode formed on a semiconductor substrate; an insulation layer having regions each having different thickness; and a top electrode disposed on a region of the insulation layer that has a relatively thick thickness.

Embodiments relate to a method for fabricating a capacitor of a semiconductor device, the method including: forming a first metal layer on a semiconductor substrate; forming an insulation layer on the first metal layer; forming a second metal layer on the insulation layer; forming a first mask layer having a first width on the second metal layer; etching the insulation layer to a predetermined thickness including the second metal layer from the surface of the insulation layer using the first mask layer as a mask to form a top electrode; and removing the first mask layer and then removing the insulation layer and the first metal layer using a second mask layer as a mask to form a bottom electrode, the second mask layer having a second width wider than the first width.

Embodiments relate to a method for fabricating a capacitor of a semiconductor device, the method including: forming a bottom electrode layer on a semiconductor substrate; sequentially forming an insulation layer and a top electrode layer on the semiconductor substrate having the bottom electrode layer; coating a photoresist layer on the semiconductor substrate having the top electrode layer, and then performing a first mask process to form a first mask layer; forming the top electrode by using the first mask layer for etching, and simultaneously etching the insulation layer to leave a predetermined thickness on both sides of the top electrode; and performing a second mask process on the semiconductor substrate having the top electrode to form a second mask layer, and then performing an etching process to form a bottom electrode.

### BRIEF DESCRIPTION OF THE DRAWINGS

FIGS. 1A to 1F are example sectional views illustrating a method for fabricating a capacitor.

FIGS. 2A to 2E are example sectional views illustrating a method for fabricating a capacitor of a semiconductor device in accordance with embodiments.

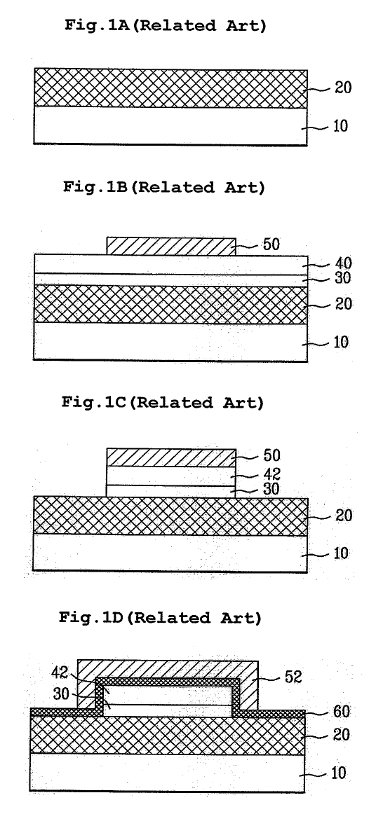

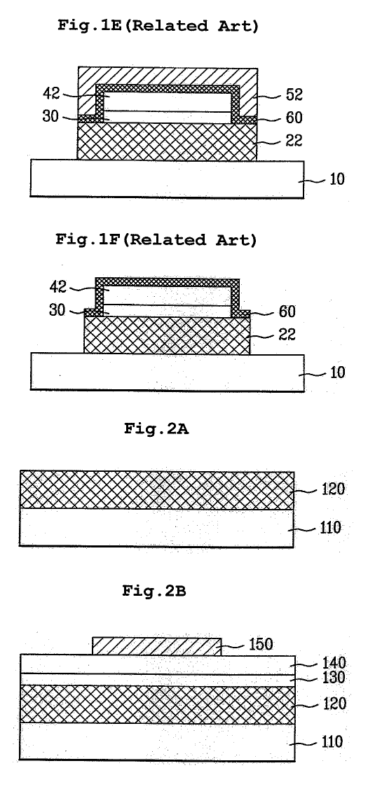

### DETAILED DESCRIPTION OF THE INVENTION

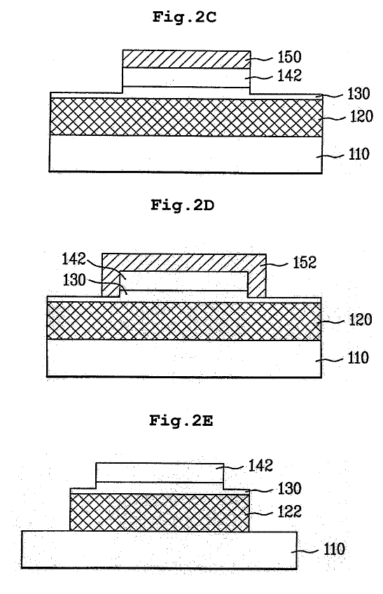

FIGS. 2A to 2E are example sectional views illustrating a method for fabricating a capacitor of a semiconductor device, in accordance with embodiments. An example method for fabricating a capacitor of a semiconductor device are described step by step with reference to FIGS. 2A to 2E.

FIG. 2A illustrates bottom electrode layer 120, which may be formed over semiconductor substrate 110 (e.g. a silicon wafer using metal or metal nitride), according to embodiments. Bottom electrode 120 may be formed of a heat-resistant metal. In embodiments, a heat-resistant metal may include at least one of Ta, TaN, Ti, TiN, Pt, Ru, Cu, W, and WN.

FIG. 2B illustrates insulation layer 130 and top electrode layer 140, which may be sequentially formed over bottom electrode layer 120, according to embodiments. Insulation layer 130 may formed of a single layer or a multi layer of SiN or SiON. Top electrode layer 140 may be formed of a heat-resistant metal. In embodiments, a heat-resistant metal may include at least one of Ta, TaN, Ti, TiN, Pt, Ru, Cu, W, and WN. A photoresist layer may be formed over top electrode layer 140. A photoresist layer may be patterned to form first mask layer 150. First mask layer 150 may have the width of a top electrode of a capacitor in a semiconductor device.

FIG. 2C illustrates, top electrode layer 140 and insulation layer 130 etched by a predetermined amount, according to embodiments. Etching may use first mask layer 150 as an etching mask. In embodiments, etching may be a plasma reactive ion etching process using F-based gas. In embodiments, etching may be a dry etching process using Cl₂, N₂, and BCl₃ as an etching gas.

In an etching process, the amount of etching may be controlled to adjust the height difference between regions masked first mask layer 150 and unmasked regions. In unmasked regions, insulation layer 130 may be maintained with a predetermined thickness (e.g. approximately 100 Å) on the bottom electrode layer 120, in accordance with the control of an etching process. Accordingly, the width of insulation layer 130 in masked regions (i.e. regions in contact with top electrode 142) may smaller than the width of insulation layer 130 in unmasked regions (i.e. the lower portion of insulation layer 130 in contact with bottom electrode layer 120). After etching of top electrode layer 140 and insulation layer 130, first mask layer 150 may be removed.

The amount of etching (i.e. etching time) may be adjusted such that insulation layer 130 has a predetermined thickness. First mask layer 150 is patterned such that insulation layer 130 has less thickness in the patterned area than in the area under electrode 142.

In embodiments, patterning may be accomplished using a diffraction mask or a half-tone mask. In embodiments, when patterning is accomplished using a diffraction mask or a half-one mask, etching is performed to etch the insulation layer 130 to have a predetermined thickness on edge regions on both sides of top electrode 142.

FIG. 2D illustrates a photoresist layer formed over semiconductor substrate 110, according to embodiments. Photoresist layer may be patterned to form second mask layer 152. Second mask layer 152 may have a width greater than the width of electrode 142.

FIG. 2E illustrates the result of using second mask layer 152 as an etching mask, according to embodiments. In embodiments, an etching process is a plasma reactive ion etching process using F-based gas or a dry etching process using Cl₂, N₂, and BCl₃. Insulation layer 130 and bottom electrode layer 120 may be etched to form bottom electrode 122 under insulation layer 130. Second mask layer 152 may be removed to complete a capacitor of a semiconductor device.

In embodiments, when etching top electrode layer 140, insulation layer 130 is formed with a predetermined thickness on the bottom electrode 122. Accordingly, in embodiments, high reflectivity of bottom electrode 122 may be decreased. In embodiments, the number of steps for capacitor fabrication may be reduced.

In embodiments, insulation layer 130 may be formed on bottom electrode 122 and may serve as a barrier between top electrode 142 and bottom electrode 122. Accordingly, in embodiments, due to the substantial elimination or significant reduction of leakage current between top electrode 142 and bottom electrode 122, reliability and quality characteristics of a capacitor may improve.

In embodiments, during etching of top electrode 142, insulation layer 130 is formed on bottom electrode 122 is etched to have a predetermined thickness. Accordingly, in embodiments, high-refractivity of bottom electrode 122 is reduced. In embodiments, the number of capacitor manufacturing processing steps is reduced.

In embodiments, insulation layer 130 formed on bottom electrode 122 prevents leakage current between top electrode 142 and bottom electrode 122. Accordingly, in embodiments, improved capacitor characteristics can be achieved, improving reliability and quality of a device.

It will be obvious and apparent to those skilled in the art that various modifications and variations can be made in the embodiments disclosed. Thus, it is intended that the disclosed embodiments covers the obvious and apparent modifications and variations, provided that they are within the scope of the appended claims and their equivalents.

What is claimed is:

1. An apparatus comprising a capacitor, wherein the capacitor comprises:
a bottom electrode formed on a semiconductor substrate;
an insulation layer having a first region and a second region, wherein thickness of the insulation layer is greater in the first region than in the second region; and
a top electrode formed over the first region of the insulation layer.

2. The apparatus of claim 1, wherein the second region of the insulation layer is to the sides of the top electrode.

3. The apparatus of claim 2, wherein the thickness of the second region of the insulation layer is approximately 100 Å.

4. The apparatus of claim 1, wherein the insulation layer comprises at least one layer of at least one of SiN and SiON.

5. The apparatus of claim 1, wherein leakage current between the top electrode and the bottom electrode is substantially prevented using bottom edges of the insulation layer.

6. A method comprising:
forming a first metal layer on a semiconductor substrate;
forming an insulation layer on the first metal layer;
forming a second metal layer on the insulation layer;
forming a first mask layer having a first width on the second metal layer;
etching the insulation layer to a predetermined thickness including the second metal layer from the surface of the insulation layer using the first mask layer as a mask to form a top electrode; and
removing the first mask layer and then removing the insulation layer and the first metal layer using a second mask layer as a mask to form a bottom electrode, the second mask layer having a second width wider than the first width.

7. The method of claim 6, wherein the insulation layer is formed of one of a single layer and a multi layer of one of SiN and SiON.

8. The method of claim 6, wherein the method is for fabricating a capacitor of a semiconductor device.

9. A method comprising:
forming a bottom electrode layer over a semiconductor substrate;
sequentially forming an insulation layer and a top electrode layer over the semiconductor substrate and the bottom electrode layer;
forming a photoresist layer over the semiconductor substrate and the top electrode layer;
forming a first mask layer;
etching the top electrode layer to form a top electrode using the first mask layer as an etch mask;
partially etching the insulation layer using the first mask layer as an etch mask, wherein the insulation layer is etched to a predetermined thickness on sides of the top electrode; and
forming a second mask layer over the top electrode and a portion of the insulation layer that was etched to a predetermined thickness; and
forming a bottom electrode using the second mask layer as an etch mask.

10. The method of claim 9, wherein the bottom electrode layer at least one heat-resistant metal, wherein said at least one heat-resistant meal comprises at least one of Ta, TaN, Ti, TiN, Pt, Ru, Cu, W, and WN.

11. The method of claim 9, wherein the insulation layer is formed of one of a single layer and a multi layer of one of SiN and SiON.

12. The method of claim 9, wherein the top electrode layer comprises at least one heat-resistant metal, wherein said at least one heat-resistant metal comprises at least one of Ta, TaN, Ti, TiN, Pt, Ru, Cu, W, and WN.

13. The method of claim 9, wherein the thickness of the insulation layer on the sides of the top electrode is approximately 100 Å.

14. The method of claim 9, wherein the first mask layer is at least one of a diffraction mask and a half-tone mask.

15. The method of claim 9, wherein the insulation layer on the sides of the top electrode is formed by controlling an etching amount.

16. The method of claim 9, wherein the method does not comprise a process reducing reflectivity.

17. The method of claim 9, wherein the method is for fabricating a capacitor of a semiconductor device.
